(19) United States
(12) Patent Application Publication
(10) Pub. No.: US 2002/0177050 A1
(43) Pub. Date: Nov. 28, 2002

(54) Phase shift mask and design method therefor

(75) Inventor: Satsuki Tanaka, Tokyo (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/152,809

(22) Filed: May 23, 2002

(30) Foreign Application Priority Data
May 24, 2001 (JP) 2001-154994

(51) Int. Cl. G03F 9/00; G03G 16/00

(52) U.S. Cl. 430/5; 430/322; 716/19; 716/21

(57) ABSTRACT

After a plurality of main patterns are placed at a predetermined pitch P, the individual main patterns are extended by a predetermined resize quantity Δ to form virtual regions. When the virtual regions have an overlapped part, the overlapped part is placed between the virtual regions, and is set as a halftone region forming part having a predetermined transmission factor T with respect to exposure light. The resize quantity Δ and the transmission factor T are set such that a transferred size of the main patterns on a predetermined resist film is settled within a desired range according to the change of the pitch P under a predetermined exposure condition.

### BACKGROUND OF THE INVENTION

1. Technical Field of the Invention

The present invention relates to a phase shift mask used in a lithography process as one manufacturing process for a semiconductor integrated circuit device (LSI), and specifically relates to a phase shift mask including a halftone region, an auxiliary pattern region, or both of them, and a design method of the phase shift mask.

2. Description of the Related Art

As the operation speed and the integration of semiconductor devices have been increasing in the LSI recently, it is required to miniaturize different types of patterns on layers constituting the semiconductor devices. Because the design rule has decreased to about a half of the wavelength of exposure light (an exposure wavelength) recently, it is extremely difficult to use a photo mask to transfer and form a pattern having a size equal to or less than the half of the exposure light wavelength on a resist film in a conventional exposure method. Different methods have been developed, and some of them are practically used.

When contact holes and via holes (simply referred to as “holes” hereafter) having different placement pitches are formed on a semiconductor substrate (a wafer) in a photo lithography process using a photo mask, it has been well known to apply the optical proximity correction (OPC) processing. The “OPC processing” means processing to correct the dimension and shape of a pattern on the mask (also referred to as “original pattern” hereafter) in advance such that a pattern to be transferred and formed on a resist film on a wafer (also referred to as “transferred pattern” hereafter) has desired dimension and shape when a mask is designed while considering a fact that the transferred pattern has a dimension and a shape different from those of the original pattern.

When the “OPC processing” is conducted, generally, for the individual hole forming patterns placed on the mask, a distance to a neighboring hole forming pattern is calculated, and it is determined whether a correction for the dimension and the shape of the hole forming pattern is necessary based on the distance. When it is determined that the correction is necessary to some of the hole forming patterns, the dimension of these hole forming patterns is changed and adjusted based on a relationship between a distance between the hole forming patterns, and the correction quantity set in advance.

Other than this method for adjusting the dimension of the hole forming pattern (an original pattern), there is a method for using an interference phenomenon of a transmitted light with an opposite phase. A photo mask using this method is known as a “phase shift mask”. This “phase shift mask” uses a phase difference of transmitted light to increase the manufacturing limit (resolving power) and the focal depth of the photolithography which depend on exposure wavelength without changing the exposure wavelength. There are different types for the “phase shift mask” such as halftone type, Levenson type, auxiliary pattern type, edge enhancement type, and chromeless type.

The “halftone type phase shift mask” is one type of the “phase shift mask”, and a halftone film (a halftone region) which slightly transmits exposure light is formed on a region where light should be shielded completely. This type of the phase shift mask generates a phase difference of about 180° between exposure light transmitting through the halftone region, and exposure light transmitting through a transparent region (mainly a pattern forming translucent region), and consequently increases a ratio of transmitted light intensity in a boundary between the halftone region and the main pattern forming translucent region to obtain a transmitted light intensity distribution having a high contrast. In this way, the influence of a diffraction of the exposure light transmitting through the main pattern forming translucent region is mitigated or eliminated, and the resolving power and the focal depth are increased without changing exposure wavelength.

It is proposed to apply an action of the halftone region for reducing the transmission light intensity around the main pattern forming translucent region to the OPC processing in Japanese Patent Application H12-303844 (not disclosed) of the same applicant. The halftone region is placed around a hole forming pattern to correct the dimension of a transferred pattern on a wafer in this proposal in this proposal. In this proposal, the width of the halftone region is determined based on a distance to other neighboring hole forming pattern as in the methods generally conducted in the OPC processing.

It is known that the “auxiliary pattern type phase shift mask” is effective for extending the focal depth of the hole forming pattern other than the “halftone type phase shift mask”. A minute “auxiliary pattern” is added around the hole forming pattern in this mask. The “auxiliary pattern” is formed smaller than the resolution limit so as not to be transferred on the wafer.

The “auxiliary pattern type phase shift mask” provides a focal depth extension effect when it is combined especially with an “oblique incident illumination” such as a zonal illumination. The “oblique incident illumination” uses only oblique incident light for illuminating the photo mask, and uses two beams comprising 0th order diffraction light and +1th order diffraction light or −1st order diffraction light to form an image on the resist film on the wafer. Namely, the principle of “two-beam interference imaging” is used. Because either one of the +1st order diffraction light and the −1st order diffraction light is used, the angle of the incident light against the photo mask is halved, and consequently, the blurring of the image is restricted when the focal position is displaced.

Usually, an “aperture” in a special shape is provided at the focal position of a fly eye lens to remove a vertical incident component of the illumination for the photo mask, and to realize the “oblique incident illumination”. The illumination light coming out from eyes around the center of the fly eye lens vertically enters the photo mask, and light coming out from eyes on the periphery of the fly eye lens obliquely enters the photo mask. When the aperture in the special shape covers the eyes around the center of the fly eye lens, illumination light obliquely entering the photo mask is obtained, and the “oblique incident illumination” is realized.

The “oblique incident light” is categorized by the shape of the “aperture” into a zonal illumination (an aperture in a ring shape), a four-point illumination (an aperture having four openings on the periphery), and two-point illumination (an aperture having two openings on the periphery).

It is known that the focal depth extension effect is remarkable when the hole forming pattern is placed densely, namely the placement pitch of the hole forming pattern is small, for the “oblique incident illumination”. Thus, the placement of the “auxiliary pattern” combined with the “oblique incident illumination” is important.

The focal depth extension effect is obtained when the placement pitch of the hole forming pattern is 1.2 to 1.6 times of the wavelength λ of the exposure light in the “oblique incident illumination”. When the placement pitch is large than 1.6 times of the wavelength λ, the +1st diffraction light or −1st diffraction light which is not used transmits through a project lens again, and the focal depth does not extends. Though the limit resolution determines the lower limit which provides the focal depth extension effect, a pitch less than the wavelength λ is not preferable because too small placement pitch exceeds the resolution limit. Thus, it is preferable that the placement pitch of the auxiliary pattern and the hole forming pattern (main pattern) is 1.2 to 1.6 times of the wavelength λ.

For example, when KrF excimer laser light is used as the exposure light, because the exposure wavelength is λ=0.248 μm, the placement pitch for the auxiliary pattern and the hole forming pattern (main pattern) is set to about 0.3 to 0.4 μm.

The width of the halftone region is determined based on the distance to a neighboring other hole forming pattern in the conventional “halftone type phase shift mask” (including Japanese Patent Application H12-303844) described above. Namely, it is investigated how far another main pattern (another hole forming pattern) exists from the main pattern (the hole forming pattern) to be corrected, and the width of the halftone region is determined based on the obtained distance. Thus, there is such a problem as it takes a long time to determine the width of the halftone region.

When the placement pitch of the main pattern (the hole forming pattern) is small on the mask, the dimension of the transferred pattern on the wafer is fairly lager than a desired value, and there is such a problem as the neighboring transferred patterns may come in contact with each other.

On the other hand, when the placement pitch of the main pattern (the hole forming pattern) is small on the mask in the conventional auxiliary pattern type phase shift mask described above, though the focal depth extension effect becomes remarkable, it is necessary to place the auxiliary pattern at the optimal position. There is such a problem as it is not easy to know the optimal position.

### SUMMARY OF THE INVENTION

An object of the present invention is to provide a phase shift mask and a design method for the phase shift mask for easily manufacturing a phase shift mask including a “halftone region” and an “auxiliary pattern”.

Another object of the present invention is to provide a phase shift mask and the design method for it which can reduce time required for designing the “halftone region” and the “auxiliary pattern”.

Another object of the present invention is to provide a phase shift mask and the design method for it which effectively restrain a deformation of a transferred pattern transferred on a wafer corresponding to an original pattern placed on the mask at a predetermined pitch.

Another object of the present invention is to provide a phase shift mask and the design method for it which surely provide a focal depth extension effect.

A design method for a phase shift mask according to a first aspect of the present invention comprises the steps of placing a plurality of main patterns at a predetermined pitch, extending the individual main patterns by a predetermined resize quantity to form virtual regions, placing an overlapped part between their two virtual regions, and setting it as a halftone region forming part having a predetermined transmission factor with respect to exposure light when the two neighboring virtual regions have the overlapped part, and setting such that the halftone region forming part does not exist when the two neighboring virtual regions do not have an overlapped part. The resize quantity and the transmission factor are set such that a transferred size of the main patterns on a predetermined resist film is settled within a desired range according to the change of the pitch under a predetermined exposure condition.

The each of said plurality of main patterns are extended by the predetermine resize quantity to form the virtual regions in the design method for a phase shift mask relating to the first aspect of the present invention. When the neighboring two virtual regions have an overlapped part, the overlapped part is placed between these two virtual regions, and is set as the halftone region forming part having the predetermined transmission factor with respect to the exposure light. When the neighboring two virtual regions do not have the overlapped part, it is set such that the halftone region forming part does not exist. The resize quantity and the transmission factor are set such that the transferred size of the main patterns on the predetermined resist film is settled within the desired range according to the change of the pitch under the predetermined exposure condition.

As a result, the halftone region forming part (namely a halftone region on the mask) can be set straight forward. Thus, the time required for setting the halftone region on the mask can be reduced, in other words, this type of the phase shift mask is manufactured more easily than in the conventional manufacture.

Further, because the design is conducted in the way described above, a deformation of the transferred patterns transferred on the wafer corresponding to the plurality of main patterns (the original patterns) placed on the mask at the predetermined pitch is effectively restrained.

The resize quantity and the transmission factor are set such that a fluctuation of the transferred dimension of the main pattern on the resist film is approximately the minimum according to the change of the pitch in a preferred embodiment of the design method for a phase shift mask of the first aspect of the present invention.

The halftone region forming part is placed along the perpendicular bisector of a line connecting the centers of the neighboring two main patterns with each other in a preferred embodiment of the design method for a phase shift mask of the first aspect of the present invention.

A phase shift mask of a second aspect of the present invention is manufactured using the design method for a phase shift mask of the first aspect of the present invention.

The phase shift mask of the second aspect of the present invention comprises a plurality of main pattern forming translucent regions formed on the surface of the substrate at the predetermined pitch, a halftone region formed between the two neighboring main pattern forming translucent regions on the surface of the substrate, and a light shield region formed on a part other than the plurality of main pattern forming translucent regions and the halftone regions. The halftone region has the feature for making the exposure light transmitting through the halftone region attenuate the intensity of the exposure light transmitting through the plurality of main pattern forming translucent regions. The position, the shape, and the size of the halftone region are respectively equivalent to the position, the shape, and the size of a part where the virtual regions obtained by extending the individual main pattern forming translucent regions by the predetermined resize quantity overlap each other.

As a result, the halftone region can be set straight forward. Thus, the time required for setting the halftone region can be reduced, in other words, the phase shift mask is manufactured more easily than in the conventional manufacture.

Further, as a result of the constitution described above, a deformation of the transferred patterns transferred on the wafer corresponding to the main pattern forming translucent regions (namely the original pattern) placed on the substrate at the predetermined pitch is effectively restrained.

The phase shift mask may further comprises a halftone film formed on the surface of the substrate, and a light shield film formed on the halftone film, and the halftone region is defined by a first opening formed on the light shield film, and the main pattern forming translucent regions are defined by second openings formed on the light shield film, and openings formed on the halftone film in a preferred embodiment of the phase shift mask of the first aspect of the present invention.

The halftone region may be placed along the perpendicular bisector of a line connecting the centers of the neighboring two main patterns with each other in a preferred embodiment of the halftone type phase shift mask of the present aspect of the invention.

A design method for a phase shift mask relating to a third aspect of the present invention comprises the steps of placing a main pattern, extending the main pattern by a predetermined first resize quantity to form a first virtual region, extending the main pattern by a predetermined second resize quantity larger than the first resize quantity to form a second virtual region, and setting a part between the second virtual region and the first virtual region to an auxiliary pattern forming part having a predetermined transmission factor. The first resize quantity and the second resize quantity are set such that a desired focal depth extension effect is obtained for exposure light under a predetermined exposure condition.

In the design method for phase shift mask of the third aspect of the present invention, after the main pattern is placed, the main pattern is extended by the predetermined first resize quantity to form the first virtual region, and the main pattern is extended by the predetermined second resize quantity larger than the first resize quantity to form the second virtual region. The part between the second virtual region and the first virtual region is set to the auxiliary pattern forming part having the predetermined transmission factor. The first resize quantity and the second resize quantity are set such that a desired focal depth extension effect is obtained for the exposure light under the predetermined exposure condition.

As a result, the auxiliary pattern forming part (namely an auxiliary pattern region on the mask) can be set straight forward. Thus, the time required for setting the auxiliary pattern region on the mask can be reduced, in other words, this type of the phase shift mask is manufactured more easily than in the conventional manufacture.

Because the design is conducted as described above, the focal depth extension effect is surely provided.

The auxiliary pattern forming part is formed as a ring concentric with the main pattern in a preferred embodiment of the design method for a phase shift mask of the third aspect of the present invention.

A phase shift mask relating to a fourth aspect of the present invention is manufactured using the design method for a phase shift mask of the third aspect of the present invention.

The phase shift mask of the fourth aspect of the present invention comprises a main pattern forming translucent region formed on the surface of the substrate, an auxiliary pattern region in a ring shape formed around the main pattern forming translucent region on the surface of the substrate, and a light shield region formed on the part other than the main pattern forming translucent region and the auxiliary pattern region. The auxiliary pattern region has the feature for making exposure light transmitting through the auxiliary pattern region attenuate the intensity of the exposure light transmitting through the main pattern forming translucent region.

The position, the shape, and the size of the auxiliary pattern region are respectively equivalent to the position, the shape, and the size of the part between the first virtual region obtained by extending the main pattern forming translucent region by the first resize quantity, and the second virtual region obtained by extending the main pattern forming translucent region by the second resize quantity larger than the first resize quantity.

As a result, the auxiliary pattern region can be set straight forward. Thus, the time required for setting the auxiliary pattern region can be reduced, in other words, this type of the phase shift mask is manufactured more easily than in the conventional manufacture.

Because the design is conducted as described above, the focal depth extension effect is surely provided.

The phase shift mask further comprises the halftone film formed on the surface of the substrate, the transparent film formed on the halftone film, and the light shield film formed on the transparent film, and the halftone region is defined by the first opening formed on the light shield film, and the main pattern forming translucent region is defined by the second opening formed on the light shield film, and the opening formed on the halftone film in a preferred embodiment of the phase shift mask of the fourth aspect of the present invention.

A design method for a phase shift mask relating to a fifth aspect of the present invention comprises the steps of placing a plurality of main patterns at a predetermined pitch, extending the each of the plurality of main patterns by a predetermined first resize quantity to form first virtual regions, extending the each of the plurality of main patterns by a predetermined second resize quantity larger than the first resize quantity to form second virtual regions, placing an overlapped part between the two first virtual regions, and setting it as a halftone region forming part having a predetermined transmission factor with respect to exposure light when the two neighboring first virtual regions have the overlapped part, setting such that the halftone region forming part does not exist when the two neighboring first virtual regions do not have an overlapped part, and setting a part where the two second virtual regions surround the two first virtual regions corresponding to them to an auxiliary pattern forming part having a predetermined transmission factor. The first resize quantity and the transmission factor of the halftone region forming part are set such that a transferred size of the main patterns on a predetermined resist film is settled within a desired range according to the change of the pitch under a predetermined exposure condition, and the second resize quantity is set such that a desired focal depth extension effect is obtained for the exposure light under the predetermined exposure condition.

In the design method for a phase shift mask of the fifth aspect of the present invention, after the plurality of main patterns are placed at the predetermined pitch, the individual main patterns are extended by the predetermined first resize quantity to form the first virtual regions. The individual main patterns are extended by the predetermined second resize quantity larger than the first resize quantity to form the second virtual regions. When the two neighboring first virtual regions have the overlapped part, the overlapped part is placed between the two first virtual regions, and is set as the halftone region forming part having the predetermined transmission factor with respect to the exposure light. When the two neighboring first virtual regions do not have the overlapped part, it is set such that the halftone region forming part does not exist. The part where the two second virtual regions surround the two first virtual regions corresponding to them is set to the auxiliary-pattern forming part having the predetermined transmission factor.

The first resize quantity and the transmission factor of the halftone-region forming part are set such that the transferred size of the main pattern on the predetermined resist film is settled within the desired range according to the change of the pitch under the predetermined exposure condition. The second resize quantity is set such that the desired focal depth extension effect is obtained for the exposure light under the predetermined exposure condition.

As a result, the halftone region forming part and the auxiliary pattern forming part (namely a halftone region and an auxiliary pattern region on the mask) can be set straight forward. Thus, the time required for setting the halftone region and the auxiliary pattern region on the mask can be reduced, in other words, this type of the phase shift mask is manufactured more easily than in the conventional manufacture.

Because the design is conducted in the way described above, a deformation of the transferred patterns transferred on the wafer corresponding to the plurality of main patterns (the original patterns) placed on the mask at the predetermined pitch is effectively restrained, and the focal depth extension effect is surely obtained.

The first resize quantity and the transmission factor of the halftone region forming part are set such that a fluctuation of the transferred dimension of the main patterns on the resist film is approximately the minimum according to the change of the pitch in a preferred embodiment of the phase shift mask of the fifth aspect of the present invention.

The halftone region forming part is placed along the perpendicular bisector of a line connecting the centers of the neighboring two main patterns with each other in a preferred embodiment of the phase shift mask of the fifth aspect of the present invention.

The auxiliary pattern forming part is formed as a ring concentric with the main pattern in a preferred embodiment of the phase shift mask of the fifth aspect of the present invention.

A phase shift mask of a sixth aspect of the present invention comprises a plurality of main pattern forming translucent regions formed on the surface of a substrate at a predetermined pitch, a halftone region formed between the two neighboring main pattern forming translucent regions on the surface of the substrate, an auxiliary pattern region in a ring shape formed around the neighboring two main pattern forming translucent regions on the surface of the substrate, and a light shield region formed on a part other than the main pattern forming translucent regions, the halftone region, and the auxiliary pattern region on the surface of the substrate. The halftone region has a feature for making exposure light transmitting through the halftone region attenuate the intensity of the exposure light transmitting through the main pattern forming translucent regions, the position, the shape, and the size of the halftone region are respectively equivalent to the position, the shape, and the size of an region where virtual regions obtained by extending the individual main pattern forming translucent regions by a predetermined resize quantity overlap each other, the auxiliary pattern region has a feature for making exposure light transmitting through the auxiliary pattern region attenuate the intensity of the exposure light transmitting through the main pattern forming translucent regions, and the position, the shape, and the size of the auxiliary pattern region are respectively equivalent to the position, the shape, and the size of an region between a first virtual region obtained by extending the main pattern forming translucent region by a first resize quantity, and a second virtual region obtained by extending the main pattern forming translucent region by a second resize quantity larger than the first resize quantity.

The phase shift mask relating to the sixth aspect of the present invention is manufactured using the design method for a phase shift mask of the fifth aspect of the present invention.

The phase shift mask of the sixth aspect of the present invention corresponds to a combination of the phase shift mask of the second aspect of the present invention and the phase shift mask of the fourth aspect of the present invention. As a result, the halftone region forming part and the auxiliary pattern forming part (namely a halftone region and an auxiliary pattern region on the mask) can be set straight forward. Thus, the time required for setting the halftone region and the auxiliary pattern region on the mask can be reduced, in other words, this type of the phase shift mask is manufactured more easily than in the conventional manufacture.

Because the design is conducted in the way described above, a deformation of the transferred patterns transferred on the wafer corresponding to the plurality of main patterns (the original patterns) placed on the mask at the predetermined pitch is effectively restrained, and the focal depth extension effect is surely obtained.

The phase shift mask may further comprises a halftone film formed on the surface of the substrate, a transparent film formed on the halftone film, and a light shield film formed on the transparent film, and the halftone region is defined by a first opening formed on the light shield film and the first opening formed on the transparent film, the auxiliary pattern region is defied by a second opening formed on the light shield film, and the individual main pattern forming translucent regions are defined by a third opening formed on the light shield film, the second opening formed on the translucent film, and openings formed on the halftone film in a preferred embodiment of the phase shift mask of the sixth form of the present invention.

The halftone region is placed along the perpendicular bisector of a line connecting the centers of the neighboring two main patterns with each other in a preferred embodiment of the phase shift mask of the sixth aspect of the present invention.

The “halftone region” is a region to transmit a part of the exposure light (so-called a semitransparent region), and it is enough that the transmission factor with respect to the exposure light is lower than that in the main pattern forming translucent region in the present invention. It is not necessary that the transmission factor is about 50%. The transmission factor in the “halftone region” is set so properly as the “halftone region” provides a desired feature.

The “auxiliary pattern region” is a region to transmit a part of the exposure light (so-called a semitransparent region), and it is enough that the transmission factor with respect to the exposure light is lower than that in the main pattern forming translucent region. The transmission factor in the “auxiliary pattern region” is set so properly as the “auxiliary pattern region” provides a desired feature.

### BRIEF DESCRIPTION OF THE DRAWINGS

FIG. 1 is a conceptual drawing for showing a design method for a halftone type phase shift mask of a first embodiment of the present invention;

FIG. 2 is a top view and a section view for showing the halftone type phase shift mask of the first embodiment of the present invention, and the mask is formed using the design method shown in FIG. 1;

FIG. 3 is a chart for showing a general relationship between a placement pitch for hole forming patterns and a transferred hole dimension for a conventional normal mask and a conventional halftone type phase shift mask;

FIG. 4 is a conceptual drawing for showing a change of an overlapped state of virtual regions according to a resize quantity of the hole forming patterns in the halftone type phase shift mask of the first embodiment of the present invention;

FIG. 5 is a conceptual drawing for showing a change of an overlapped state of the virtual regions according to the pitch of the hole forming pattern in the halftone type phase shift mask of the first embodiment of the present invention;

FIG. 6 is a chart for showing a relationship between the placement pitch for the hole forming patterns and the transferred hole dimension based on an actual measurement for the halftone type phase shift mask of the first embodiment of the present invention, the conventional normal mask, and the conventional halftone type phase shift mask;

FIG. 7 is a conceptual drawing for showing a design method for an auxiliary pattern type phase shift mask of a second embodiment of the present invention;

FIG. 8 is a top view and a section view for showing the auxiliary pattern type phase shift mask of the second embodiment of the present invention which is formed using the design method shown in FIG. 7;

FIG. 9 is a conceptual drawing for showing a design method for a halftone/auxiliary pattern type phase shift mask of a third embodiment of the present invention;

FIG. 10 is a top view and a section view for showing the halftone/auxiliary pattern type phase shift mask of the third embodiment of the present invention which is formed using the design method shown in FIG. 9;

FIG. 11 is a chart for showing a relationship between a placement pitch for the hole forming pattern and a transferred hole dimension based on an actual measurement for the halftone/auxiliary pattern type phase shift mask of the third embodiment of the present invention, and the conventional halftone type phase shift mask; and

FIG. 12 is a chart for showing a relationship between a focal position and a contrast based on an actual measurement for the halftone/auxiliary pattern type phase shift mask of the third embodiment of the present invention, the conventional normal mask, and the conventional halftone type phase shift mask.

### THE PREFERRED EMBODIMENTS OF THE INVENTION

The following section specifically describes preferred embodiments of the present invention while referring to attached drawings.

(Constitution of Mask of First Embodiment)

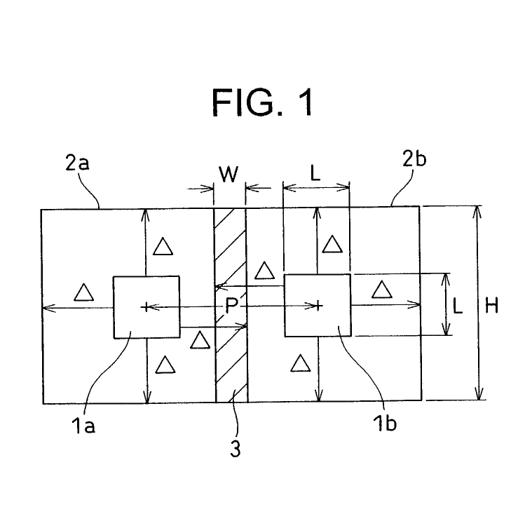

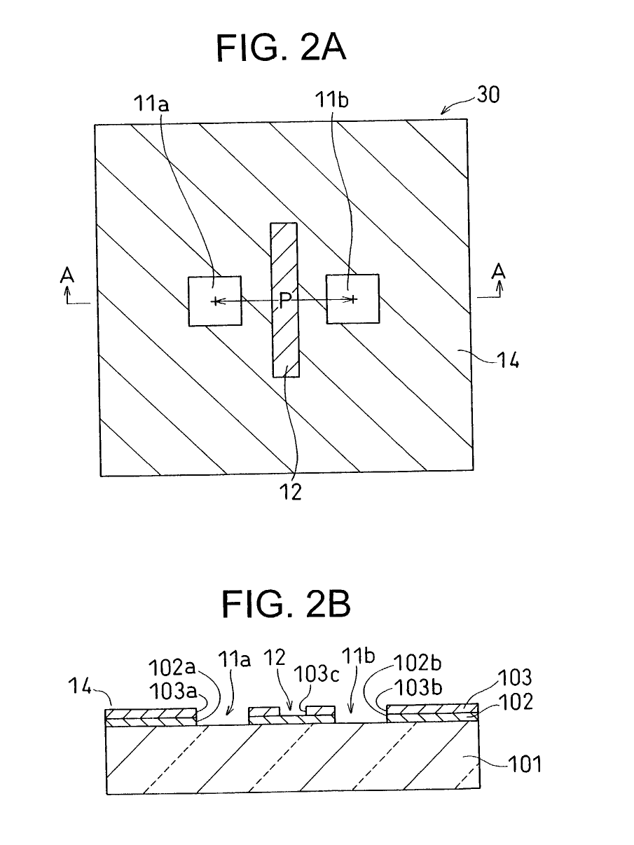

FIG. 1 is a conceptual drawing for showing a design method for a halftone type phase shift mask of a first embodiment of the present invention, and FIG. 2A and FIG. 2B are respectively a top view and a section view for showing the halftone type phase shift mask of the first embodiment of the present invention. This mask 10 is used to transfer and form two square hole forming patterns 1a and 1b placed with a pitch P as shown in FIG. 1 on a wafer. The patterns 1a and 1b have the same shape and dimension.

The halftone type phase shift mask 10 of the present invention has hole forming translucent regions 11a and 11b as the two squares placed with the pitch P, a halftone region 12 in a stripe shape (a long rectangle) placed between these translucent regions 11a and 11b, and a light shield region 14 covering around the translucent regions 11a and 11b, and the halftone region 12 on a transparent substrate 101 in FIG. 2A and FIG. 2B. The light shield region 14 is formed on a part other than the translucent regions 11a and 11b and the halftone region 12.

The two translucent regions 11a and 11b are used to transfer and form a pattern for forming a contact hole or a via hole of a semiconductor integrated circuit device (LSI) on a photo resist film on a wafer. The translucent regions 11a and 11b have a transmission factor of almost 100% with respect to predetermined exposure light.

The halftone region 12 extends along a perpendicular bisector of a line connecting the centers of the two translucent regions 11a and 11b with each other. The halftone region 12 is set such that the phase of exposure light transmitting through it is different from that of exposure light transmitting through the translucent regions 11a and 11b by about 180°.

The halftone region 12 has a transmission factor fairly lower than that of the translucent regions 11a and 11b with respect to prescribed exposure light. The transmission factor of the halftone region 12 is set such that the transmission light through the halftone region 12 does not transfer a pattern on a predetermined photo resist film, namely transmission light intensity does not expose the photo resist film, when the phase shift mask 10 is used to expose the photo resist film. The halftone region 12 is provided to increase the resolution of the mask 10, and should not be transferred on the photo resist film.

(Manufacture of Mask of First Embodiment)

The halftone type phase shift mask 10 shown in FIG. 2A and FIG. 2B comprises a mask substrate formed by sequentially laminating a halftone film 102, and a light shield film 103 on the transparent substrate 101. This phase shift mask 10 is manufactured by selectively etching the halftone mask 102 and the light shield mask 103 as follows.

First, an electron beam lithography device is used to lithograph the hole forming translucent regions 11a and 11b on a photo resist film (not shown in the drawing) formed on the light shield film 103 based on data for defining the hole forming patterns 1a and 1b shown in FIG. 1. When the photo resist film is developed, openings are formed at a positions corresponding to the translucent regions 11a and 11b on the photo resist film. Dry etching selectively removes the light shield film 103 and the halftone film 102 while the patterned photo resist film is used as a mask. Two square openings 103a and 103b are formed on the light shield film 103, and two square openings 102a and 102b are formed on the halftone film 102. Then, this photo resist film is removed.

Then, the same electron beam lithography device is used to lithograph the halftone region 12 on another resist film (not shown in the drawing) formed on the light shield film 103 based on data for the halftone region forming part 3 shown in FIG. 1. This halftone region forming part 3 is described later. When this resist film is developed, an opening is formed at a position corresponding to the halftone region 12. Dry etching selectively removes the light shield film 103 to expose the underlying halftone film 102 while this resist film is used as a mask. At this time, the halftone film 102 is not etched. An opening 103c in a rectangular shape (a stripe shape) corresponding to the halftone region 12 is formed on the light shield film 103. Then, the resist film is removed.

As described above, the halftone type phase shift mask 10 with a constitution as shown in FIG. 2A and FIG. 2B is formed. The opening 103a on the light shield film 103, and the opening 102a on the halftone film 102 form the translucent region 11a in a square shape, the opening 103b on the light shield film 103, and the opening 102b on the halftone film 102 form the translucent region 11b in a square shape, and the opening 103c on the light shield film 103 and the halftone film 102 underlying it form the halftone region 12 in this mask 10. The distance between, namely the pitch of, the translucent regions 11a and 11b is P.

A material of the transparent substrate 101 is synthetic quartz, for example. Materials of the halftone film 102 are oxide nitride molybdenum silicide (MoSiON) and chromium fluoride (CrF), for example. A material of the light shield film 103 is a laminated body of chrome and chromium oxide, for example. Materials other than these materials may be used.

When the predetermined exposure light irradiates the halftone type phase shift mask 10 of the first embodiment, the exposure light irradiates a photo resist film underlying the mask 10 through the translucent regions 11a and 11b, and the halftone region 12. Because it is set such that the phase of the exposure light transmitting through the halftone region 12 is shifted to the phase of the exposure light transmitting through the translucent regions 11a and 11b by 180°, the intensity of the transmission light decreases on a boundary of the translucent regions 11a and 11b, and the halftone region 12 because of optical interference. This effect of decreasing the transmission light intensity changes according to the area of the halftone region 12 and the transmission factor with respect to the exposure light. The effect of decreasing the intensity of the transmission light increases (namely the transmission light intensity decreases) as the transmission factor of the halftone region 12 increases, and the area of the halftone region 12 increases. With the halftone type phase shift mask 10 of the first embodiment of the present invention, when the transmission factor and the area of the halftone region 12 are properly set, such a problem as the hole forming patterns 1a and 1b transferred and formed on the photo resist film on the wafer become excessively larger than desired sizes, and the transferred and formed hole forming patterns 1a and 1b are connected with each other in an extreme case is solved.

(Design Method for Mask of First Embodiment)

FIG. 1 is a conceptual drawing for showing a design method for the halftone type phase shift mask 10 (see FIGS. 2A and 2B) of the first embodiment of the present invention. A computer aided design (CAD) device is usually used for this design.

First, the two square hole forming patterns 1a and 1b are placed at the predetermined pitch P as shown in FIG. 1 on a display device (not shown) of the CAD device.

Virtual regions 2a and 2b are individually set with respect to the two hole forming patterns 1a and 1b as shown in FIG. 1. These virtual regions 2a and 2b are the extended, in other words, “resized”, hole forming patterns 1a and 1b by the same ratio while their centers are maintained coinciding with those of the hole forming patterns 1a and 1b. Thus, the virtual regions 2a and 2b are the same squares, and have the same dimension.

Δ indicates the resize quantity of the patterns 1a and 1b in FIG. 1. The same resize quantity Δ is added to extend the patterns 1a and 1b on all the four directions for forming the virtual regions 2a and 2b in the example in FIG. 1.

When the hole forming patterns 1a and 1b have the certain pitch P, and the resize quantity Δ is properly adjusted to overlap the two virtual regions 2a and 2b in a square shape as shown in FIG. 1, the overlap 3 in a rectangle shape (a stripe shape) is formed between the patterns 1a and 1b. The overlap 3 is set to the “halftone region forming part” in the present invention. The halftone region 12 is formed on the mask 10 corresponding to the data for this “halftone region forming part 3”. It is assumed that the transmission factor of the “halftone region forming part 3” with respect to exposure light is T.

As FIG. 1 clearly shows, the halftone region forming part 3 is placed on the perpendicular bisector of a line connecting the centers of the hole forming patterns 1a and 1b with each other. When an edge of the hole forming patterns 1a and 1b is L, the width W and the height H of the halftone region 3 are:

W=2Δ+L−PW, and

H=L+2Δ.

The area S of the halftone region forming part 3 is represented as:

S=W×H.

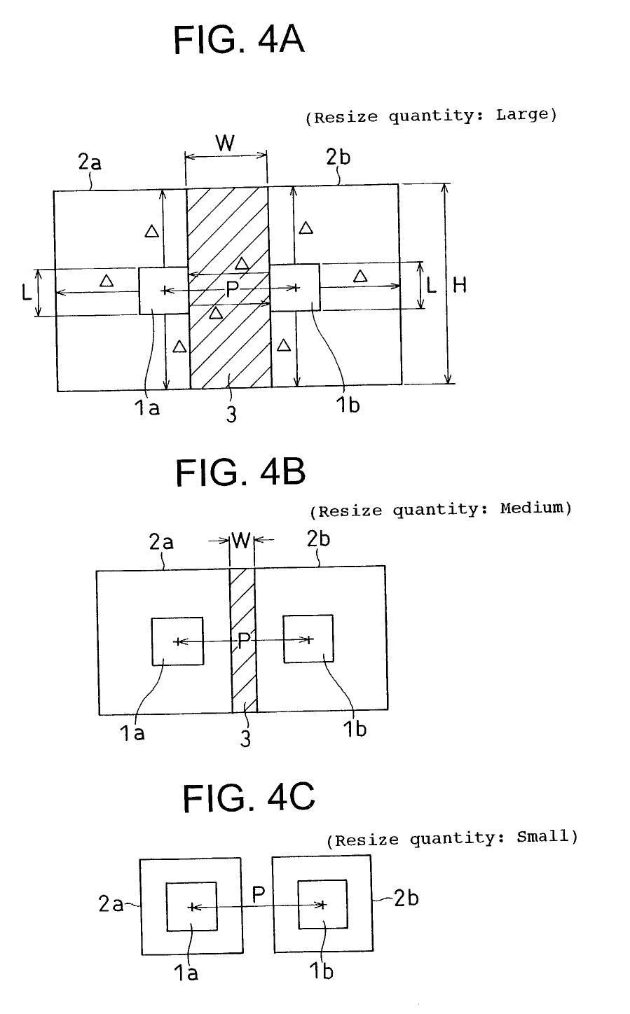

FIGS. 4A, 4B, and 4C are conceptual drawings for showing a change of an overlapped state of the virtual regions according to the pitch P of the hole forming patterns 1a and 1b.

FIG. 4B shows a state where parts of the virtual regions 2a and 2b of the patterns 1a and 1b overlap to form the halftone region forming part 3 as in FIG. 1. Though the pitch P of the hole forming patterns 1a and 1b is the same as that in FIG. 4B, because the resize quantity Δ is small, the virtual regions 2a and 2b of the patterns 1a and 1b are separated from each other, namely the halftone region forming part 3 does not exist in FIG. 4C. Though the pitch P of the hole forming patterns 1a and 1b is the same as that in FIG. 4B, because the resize quantity Δ is large, the entire virtual regions 2a and 2b overlap between the patterns 1a and 1b, namely the halftone region forming part 3 exists all over the part between the patterns 1a and 1b in FIG. 4A.

Because the structure of an LSI usually determines the pitch P of the hole forming patterns 1a and 1b, adjusting the resize quantity Δ changes the overlap of the virtual regions 2a and 2b, and the position, the dimension, and the shape of the halftone region forming part 3 is automatically set accordingly in this design method. Thus, the halftone region forming part 3, namely the halftone region 12 on the mask 10 is designed extremely easily.

In this way, while adjusting the resize quantity Δ easily determines the position, the dimension, and the shape of the halftone region forming part 3 (namely the halftone region 12), it is necessary to consider the transmission factor T of the halftone region forming part 3 (namely the halftone region 12). The feature of the halftone region 12 changes according to the transfer factor T.

The following section describes how to set the transfer factor T, the width W, and the height H (namely the area S) of the halftone region forming part 3 in the halftone type phase shift mask 10 of the first embodiment of the present invention.

When this phase shift mask 10 is designed, first, the transmission factor T of the halftone region forming part (the halftone region 12) is set to a proper value, and then, the area S of the halftone region forming part 3, namely the resize quantity Δ of the hole forming patterns 1a and 1b, is set. After the resize quaintly Δ is determined, the position, the dimension, and the shape of the halftone region forming part 3 (namely the halftone region 12) are automatically determined as shown in FIG. 1, and FIGS. 4A to 4C.

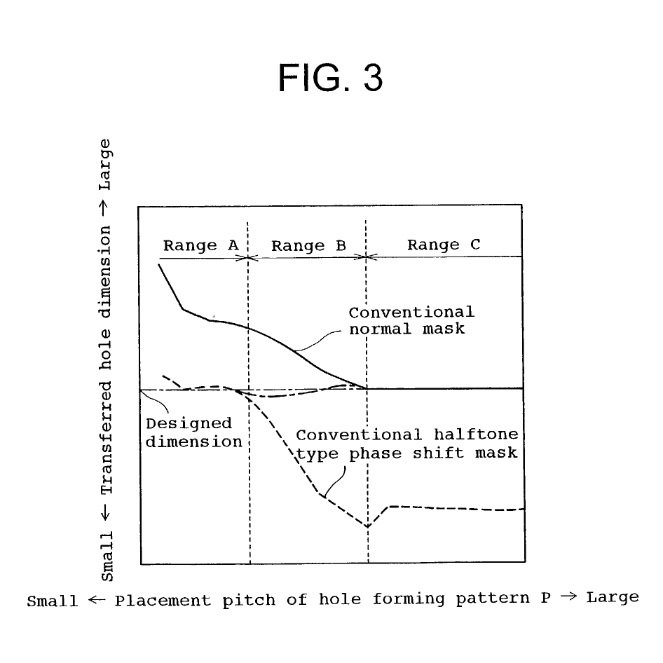

When an oblique incident illumination or a high σ illumination (σ is a coherence factor, σ>0.7) is used, the transferred hole dimension on the photo resist film on a wafer generally tends to become large because of the optical proximity effect as the hole forming patterns 1a and 1b are placed closer (the placement pitch P becomes smaller). FIG. 3 shows an example.

FIG. 3 shows a change of the transferred hole dimension on a photo resist film on a wafer with respect to the placement pitch P of the hole forming patterns 1a and 1b for the “conventional normal mask” and the “conventional halftone type phase shift mask”. The same exposure quantity is used both for the “conventional normal mask” and the “conventional halftone type phase shift mask”.

The “conventional normal mask” in FIG. 3 is a mask where the halftone film 102 is eliminated, and the light shield film 103 is directly formed on the transparent substrate 101 in the constitution in FIGS. 2A and 2B. The light shield film 103 has only the openings 103a and 103b, and there exists no opening 103c for the halftone region 12.

The “conventional halftone type phase shift mask” in FIG. 3 is a mask where the light shield film 103 is removed in the constitution in FIGS. 2A and 2B. In other words, there is only the halftone film 102 on the transparent substrate 101, and the halftone film 102 has the openings 102a and 102b.

As FIG. 3 clearly shows, the transferred hole dimension is close to the designed dimension across the entire range of the pitch P when the transmission factor of the halftone film 102 is low enough in the “conventional halftone type phase shift mask” as a dash dot indicates. However, as the transmission factor of the halftone film 102 increases, a curve indicated by a dashed line, which shows almost no change in a range A, and is largely shifted downward in ranges B and C, appears. This is close to the “conventional normal mask” simply shifted downward.

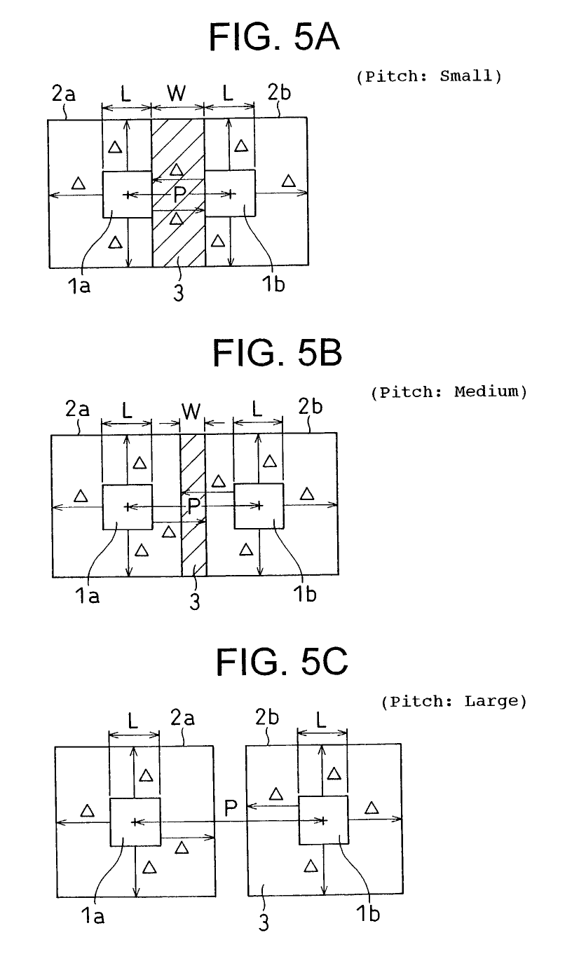

Thus, it is necessary not to add the halftone region forming part 3 to make the transferred hole dimension close to the designed dimension in the range C where the pitch P of the hole forming patterns 1a and 1b is large as shown in FIG. 5C. It is necessary to add the halftone region forming part 3, and simultaneously to increase the area S of it as the pitch P comes close to the range A from the range C in the range B where the pitch P is intermediate as shown in FIG. 5B. The width W of the halftone region forming part 3 is set to the maxim in the range A where the pitch P is small as shown in FIG. 5A. Because the width W of the halftone region forming part 3 is the maxim in the range A where the pitch P is small, the transmission factor T of the halftone region forming part 3 is adjusted such that the transferred dimension matches the designed dimension. In this way, it is possible to set the curve indicating the dimension of the transferred hole as flat as possible (a fluctuation of the dimension of the transferred holes with respect to the pitch P becomes small) in all the ranges A, B, and C of the pitch P.

It is necessary to consider the fact that the area S of the halftone region forming part 3 gradually decreases as the pitch P increases in the range B where the pitch P is intermediate.

(Specific Example of Mask of First Embodiment)

As described above, when the transmission factor T and the area S of the halftone region forming part 3 are adjusted, the curve of the transferred hole dimension comes close to flat. The following section describes an actual test conducted by the inventors to show a specific example.

The phase shift mask 10 of the first embodiment was used to transfer and form square holes with an edge of 16 μm on a photo resist film on a wafer in this test. The minimum and maximum values of the placement pitch P of these holes are 0.30 μm and 1.5 μm. A ⅔ zonal illumination (an illumination using a circular aperture to shield light in a range from the center to ⅔ of the radius) is used as an exposure device where the wavelength λ=248 nm, NA=0.68, maximum σ=0.75 as the optical conditions of the exposure light.

The dimension of the hole forming patterns 1a and 1b described below are obtained by light intensity distribution calculation using “exposure threshold model”. Namely, the distribution of the light intensity irradiated on the photo resist film on the wafer through the mask 10 is calculated, and the dimension is obtained while it is assumed that a part where the light intensity of the photo resist film is more than a certain threshold is dissolved by developing, and becomes an opening for forming a hole forming pattern. A light intensity when an isolated hole forming pattern provides a desired dimension, namely a square of 0.16 μm, is used as the threshold for the light intensity. When the placement pitch is 1 μm or more, the dimension change of the transferred hole is almost zero (namely the desired hole forming pattern is formed), it is assumed that a pattern is an isolated pattern when the placement pitch is the maximum value of 1.5 μm.

It is preferable that the transmission factor T of the halftone region forming part 3 (namely the halftone region 12) is restrained to a certain value in terms of correction precision. When the transmission factor T of the halftone region forming part 3 is too high, if the width W of the halftone region forming part 3 is changed, the dimension change of the hole forming pattern transferred on the wafer (the transferred pattern) becomes excessive. In an extreme case, though it is possible to set the transmission factor T of the halftone region forming part 3 is set to 100%, it is impossible to set the transmission factor T to this high value because the dimension of the transferred pattern on the wafer reduces largely just if an extremely narrow halftone region 12 is provided. On the other hand, the transmission factor T of the halftone region forming part 3 is too low, even if an entire part other than the hole forming translucent regions 11a and 11b on the mask 10 is set as the halftone region 12 (namely the light shield film 103 is eliminated), the transferred pattern may not have a desired dimension. Thus, there is a proper range for the transmission factor T.

In this test, the transmission factor T is set such that the dimension is the same as that of the hole forming pattern transferred on the wafer using isolated (pitch=1.5 μm) hole forming pattern when the pitch P of the hole forming patterns 1a and 1b is the minimum value of 0.30 μm, and the entire part other than the hole forming translucent regions 11a and 11b on the mask 10 is set as the halftone region 12. This is because the dimension of transferred isolated hole forming pattern is minimum, and the dimension of transferred hole forming pattern with the minimum pitch is maximum.

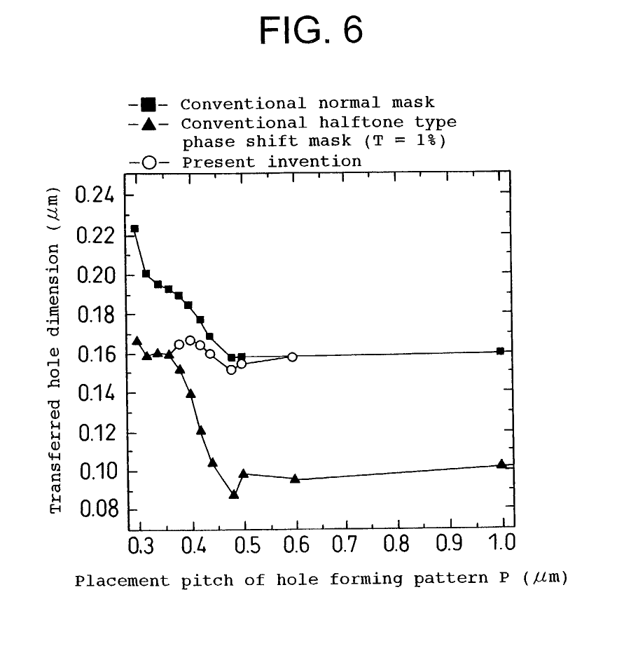

FIG. 6 is a chart for showing the change of the transferred hole dimension with respect to the placement pitch P for the hole forming patterns 1a and 1b for the “conventional normal mask”, and the “conventional halftone type phase shift mask” the same as those in FIG. 3.

According to the test of the inventors, when the “conventional halftone type phase shift mask” is used as shown in FIG. 6, the transferred hole dimension for the minimum pitch of 0.30 μm is equal to the isolated transferred hole dimension for the “conventional normal mask” when the transmission factor T of the halftone region 12 is 1% (cases other than that where the transmission factor is 1% are skipped). Thus, in this test, the transmission factor T of the halftone region forming part 3 (namely the halftone region 12) is set to 1% (T=1%).

The resize quantity Δ for generating the halftone region forming part 3 is set as follows.

As FIG. 6 clearly shows, when the transmission factor T is 1% for the “conventional halftone type phase shift mask”, if the placement pitch P is more than 0.38 μm, the transferred hole dimension largely decreases. In view of this point, the resize quantity Δ is set as follows.

Namely, the resize quantity Δ is set to 0.2 μm so that the part where the virtual regions 2a and 2b overlap between the neighboring hole forming patterns 1a and 1b, namely the halftone region 3, is in contact with the patterns 1a and 1b, namely the area S of the halftone region forming part 3 is the maximum in a range where the placement pitch P is less than 0.37 μm as shown in FIG. 4A. In this case, the width W of the halftone region forming part 3 is equal to a distance (P−L) between opposing edges of the neighboring hole forming patterns 1a and 1b (W=P−L). At this time, the mask 10 has a constitution where the width of the halftone region 12 is equal to the distance between the opposing edges of the hole forming translucent regions 11a and 11b, and the halftone region 12 is in contact with the hole forming translucent regions 11a and 11b in FIGS. 2A and 2B. The length (the height) of the halftone region 12 is fairly larger than that in FIGS. 2A and 2B.

The halftone region forming part 3 between the neighboring hole forming patterns 1a and 1b is not in contact with these patterns 1a and 1b in a range where the placement pitch P is from 0.38 μm to 0.51 μm as shown in FIG. 4B. In this case, the width W of the halftone region forming part 3 is smaller than the distance (P−L) between the opposing edges of the neighboring hole forming patterns 1a and 1b (W<P−L). At this time, the mask 10 has a constitution shown in FIGS. 2A and 2B.

The halftone region forming part 3 does not exist between the neighboring hole forming patterns 1a and 1b in a range where the placement pitch P is more than 0.52 μm as shown in FIG. 4C (W=0). Namely, the mask 10 has a constitution shown in FIGS. 2A and 2B without the halftone region 12, namely, the entire part other than the hole forming translucent regions 11a and 11b is the light shield region 14.

With the phase shift mask 10 of the first embodiment of the present invention obtained by changing the constitution according to the placement pitch P, the fluctuation of the transferred pitch dimension is restrained to a range of 0.16 μm±0.01 μm in the entire range from 0.30 μm to 1.0 μm of the placement pitch P as shown in FIG. 6.

When the optical conditions of the used exposure device, namely the exposure wavelength λ, the numerical aperture NA, and coherence factor σ, change, the optimal transmission factor T and the resize quantity Δ of the halftone forming part 3 change. However the optimization is generally conducted as follows.

First, a simulation or an experiment is conducted while a plurality of values are set to the transmission factor T and the resize quantity Δ, and the relationship between the placement pitch P of the hole forming patterns 1a and 1b, and the transferred hole dimension is obtained. A chart as shown in FIG. 6 is obtained based on this relationship. Then, this chart is used to find a combination between the transmission factor T and the resize quantity Δ which presents the minimum fluctuation of the transferred hole dimension (namely a difference between the maximum and the minimum of the transferred hole dimension) with respect to the placement pitch P. As a result, the optimal values of the transmission factor T and the resize quantity Δ, or values close to them are easily obtained.

For example, a simulation or an experiment is conducted while the transmission factor T is changed in a range from 1% to 4% with an increment of 1%, and the resize quantity Δ is changed in a range from 0.1 μm to 0.2 μm with an increment of 0.02 μm. With this, the relationship between the placement pitch P of the hole forming patterns 1a and 1b, and the transferred hole dimension is obtained. Then, the combination of the transmission factor T and the resize quantity Δ which provides the minimum fluctuation of the transferred hole dimension is obtained based on the relationship. When other optical conditions change, the same procedure is used.

In general, the difference between the transferred hole dimension and the desired dimension increases as the placement pitch decreases when the NA is small and the light shield range of the zone illumination is large. Thus, it is necessary to increase the transmission factor T to correct it.

It has recently been proposed to add a positive “mask bias” to the hole forming patterns 1a and 1b. With this, the patterns 1a and 1b are intentionally formed slightly larger than the desired dimension. When the patterns 1a and 1b formed slightly larger in this way are transferred on the wafer while they are shrunk, an influence of a manufacturing error of the mask decreases.

When a “positive mask bias” is added to the hole forming patterns 1a and 1b in view of this, because the tendency that the difference between the transferred hole dimension and the desired dimension tends to increase as the placement pitch P decreases becomes stronger, the optimal transmission factor T becomes even higher.

With the halftone type phase shift mask 10 of the first embodiment of the present invention described above, because the resize quantity Δ is used to resize the hole forming patterns 1a and 1b, their virtual regions 2a and 2b are formed, and an overlapped part of these virtual regions 2a and 2b is extracted to determine the halftone region forming part 3, the time is reduced compared with the OPC processing described as prior art, and there is such an advantage as the correction value, namely the resize quantity Δ, is determined simultaneously.

It is also possible to restrain the deformation of the transferred pattern transferred on the wafer with respect to the hole forming patterns 1a and 1b (original patterns) placed on the mask 10 at the predetermined pitch P.

(Constitution of Mask of Second Embodiment)

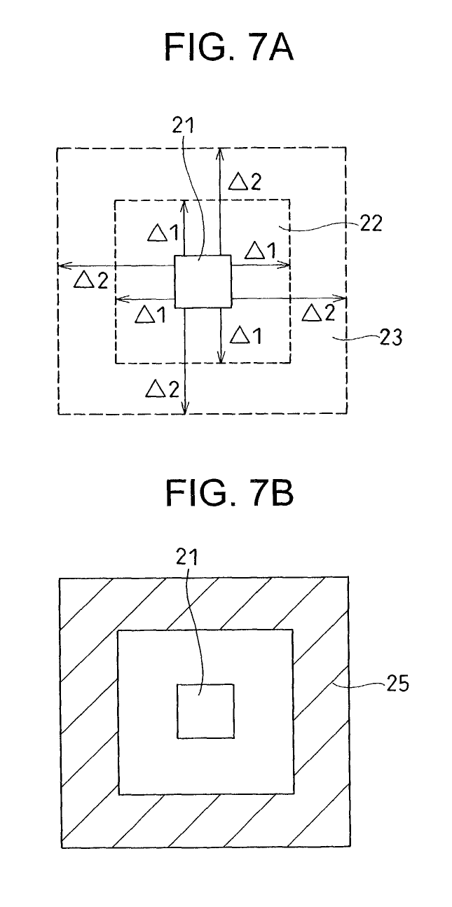

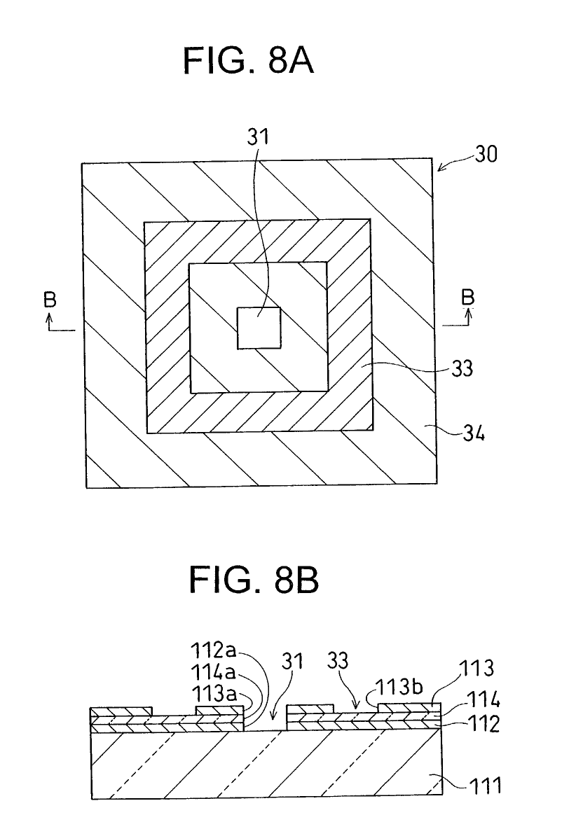

FIGS. 7A and 7B are conceptual drawings for showing a design method for an auxiliary pattern type phase shift mask of a second embodiment of the present invention, and FIGS. 8A and 8B show a constitution of an auxiliary pattern type phase shift mask 30. This mask 30 is used to transfer and form one square hole forming pattern 21 as shown in FIGS. 7A and 7B on a wafer. While the mask 10 in the first embodiment is intended to increase the precision of the transferred hole dimension, the mask 30 of the second embodiment is intended to increase the focal depth.

The phase shift mask 30 of the present invention has one isolated square hole forming translucent region 31, an auxiliary pattern region 33 in a square ring shape placed to surround the translucent region 31, and a light shield region 34 for covering the outside of the auxiliary pattern 33 on a transparent substrate 111 in FIGS. 8A and 8B. The light shield region 34 is formed on a part other than the light shield region 31 and the auxiliary pattern region 33.

The translucent region 31 is used to transfer and form a pattern for forming a contact hole and a via hole for an LSI on a photo resist film on a wafer. The translucent region 31 has the transmission factor of almost 100% with respect to predetermined exposure light.

The auxiliary pattern region 33 extends along an outer periphery of the translucent region 31 so as to surround it. The auxiliary pattern region 33 is set such that exposure light transmitting through it has almost the same phase as that of transmission light transmitting through the translucent region 31.

The auxiliary pattern region 33 has a fairly lower transmission factor than that of the translucent region 31 with respect to the predetermined exposure light. The transmission factor of the auxiliary pattern region 33 is set such that when the phase shift mask 30 is used to expose a predetermined photo resist film, the transmission light through the auxiliary pattern region 33 does not transfer a pattern on the photo resist film, namely the transmission light intensity is set so as not to expose the photo resist film. The auxiliary pattern region 33 is provided to increase the focal depth of the mask 30, and is not to be transferred on the photo resist film.

(Manufacture of Mask of Second Embodiment)

The auxiliary pattern type phase shift mask 30 shown in FIGS. 8A and 8B comprises a mask substrate formed by sequentially laminating a halftone film 112, a transparent film 114, and a light shield film 113 on the transparent substrate 111. This phase shift mask 30 is manufactured by selectively etching the halftone film 112, the transparent film 114, and the light shield mask 113 as follows.

First, an electron beam lithography device is used to lithograph the hole forming translucent region 31 on a photo resist film (not shown in the drawing) formed on the light shield film 113 based on data for defining the hole forming pattern 21 shown in FIGS. 7A and 7B. When the photo resist film is developed, an opening is formed at a position corresponding to the hole forming translucent region 31 on the photo resist film. Dry etching selectively removes the light shield film 113, the transparent film 114, and the halftone film 112 while the photo resist film is used as a mask. A square opening 112a is formed on the light shield film 113, a square opening 114a is formed on the transparent film 114, and a square opening 112a is formed on the halftone film 112. Then, this photo resist film is removed.

Then, the same electron beam lithography device is used to lithograph the auxiliary pattern region 33 on another resist film (not shown in the drawing) formed on the light shield film 113 based on data for the auxiliary pattern region forming part 33 shown in FIGS. 7A and 7B. When this photo resist film is developed, an opening is formed at a position corresponding to the auxiliary pattern region 33. Dry etching selectively removes the light shield film 113 to expose the underlying transparent film 114 while this photo resist film is used as a mask. In this way, an opening 113b in a rectangular shape corresponding to the auxiliary pattern region 33 is formed on the light shield film 113. Then, the resist film is removed.

In this way, the auxiliary pattern type phase shift mask 30 with a constitution as shown in FIGS. 8A and 8B is formed. Namely, the rectangular auxiliary pattern region 33 is placed around the one isolated square translucent region 31, and the outside of the auxiliary pattern region 33 is set as the light shield region 34.

Because the exposure light transmits through the transparent film 114 and the halftone film 112 in the auxiliary pattern region 33, the auxiliary pattern region 33 is semitransparent. While the halftone film 112 is set to shift the phase of the transmitting exposure light by 180°, the transparent film 114 is also set to shift the phase of the transmitting exposure light by 180°, and the phase of the exposure light transmitting through the auxiliary pattern region 33 is the same as that of the exposure light transmitting through the hole forming translucent region 31. The materials described in the first embodiment are used as materials for the transparent substrate 111 and the light shield film 113. As materials for the transparent film 114, SiO2 formed using chemical vapor deposition (CVD), and an arbitrary spin on glass (SOG) material are used.

When predetermined exposure light is irradiated on the auxiliary pattern phase shift mask 30, the exposure light transmits through the translucent region 31 and the auxiliary pattern region 33. Because it is set such that the phase of the exposure light transmitting through the semitransparent auxiliary pattern region 33 is the same as that of the exposure light transmitting through the hole forming translucent region 31, it is possible to extend the focal depth of the exposure light transmitting through the hole forming translucent region 31.

(Design Method for Mask of Second Embodiment)

FIGS. 7A and 7B are conceptual drawings for showing a design method for the auxiliary pattern type phase shift mask 30 (see FIGS. 8A and 8B) of the second embodiment of the present invention.

The one square hole forming pattern 21 is placed on a display device (not shown) of a CAD device as shown in FIGS. 7A and 7B.

Then, a first virtual region 22 and a second virtual region 23 are respectively set with respect to the hole forming pattern 21 as shown in FIGS. 7A and 7B. The first virtual region 22 and the second virtual region 23 are magnified (resized) using different ratios while their centers are maintained to coincide with that of the hole forming pattern 21. Thus, both of the virtual regions 22 and 23 are squares. Δ1 and Δ2 respectively represent resize quantities for the virtual regions 22 and 23. The same resize quantities Δ1 and Δ2 are added in the all four directions in the example shown in FIGS. 7A and 7B. Because the second virtual region 23 is formed outside of the first virtual region 22, there is a relationship of Δ1<Δ2 between the resize quantities Δ1 and Δ2.

The resize quantity Δ1 is the same as the resize quantity Δ obtained in the first embodiment. A part between the first virtual region 22 and the second virtual region 23, namely the region of (Δ2−Δ1), is set as an “auxiliary pattern forming part 25”. A semitransparent auxiliary pattern is formed on the auxiliary pattern region 33 formed corresponding to this auxiliary pattern region forming part 25. The phase of the exposure light transmitting through the semitransparent auxiliary pattern is the same as that of the exposure light transmitting through the hole forming translucent region 31. Thus, it is possible to extend the focal depth of the exposure light transmitting through the hole forming translucent region 31.

(Constitution of Mask of Third Embodiment)

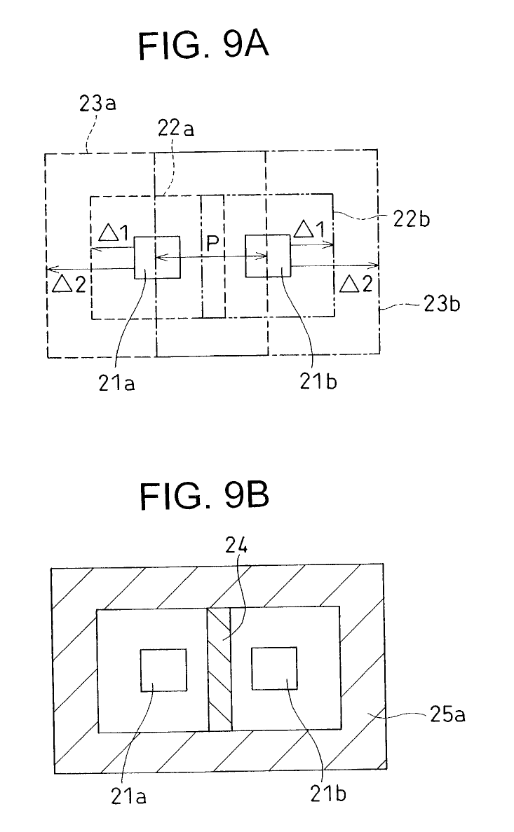

FIGS. 9A and 9B show a halftone/auxiliary pattern type phase shift mask 40 of a third embodiment of the present invention. While the present invention is applied to the isolated hole forming pattern 21 in the mask 30 in FIGS. 7A and 7B, and FIGS. 8A and 8B, the present invention is applied to neighboring two hole forming patterns in the mask 40 of the present embodiment. The mask 40 corresponds to a combination of the first embodiment and the second embodiment.

The phase shift mask 40 has two square hole forming translucent regions 41a and 41b placed with a pitch of P, a halftone region 42 in a stripe shape (a long rectangle) placed between these translucent regions 41a and 41b, an auxiliary pattern region 43 in a rectangular ring shape placed around these translucent regions 41a and 41b, and the halftone region 42, and a light shield region 44 for covering the outside of the auxiliary pattern region 43 on a transparent substrate 121 in FIGS. 9A and 9B. The light shield region 44 is formed on a part other than the translucent regions 41a and 41b and an auxiliary pattern region 33.

The translucent regions 41a and 41b are used to transfer and form a pattern for forming a contact hole or a via hole of an LSI on a photo resist film on a wafer. The translucent regions 41a and 41b have a transmission factor of almost 100% with respect to predetermined exposure light.

The halftone region 42 extends along a perpendicular bisector of a line connecting the centers of the two translucent regions 41a and 41b with each other. The halftone region 42 is set such that the phase of exposure light transmitting through it is different from that of the exposure light transmitting through the translucent regions 41a and 41b by about 180°.

The halftone region 42 has a transmission factor fairly lower than that of the translucent regions 41a and 41b with respect to prescribed exposure light. The transmission factor of the halftone region 42 is set such that the transmission light through the halftone region 42 does not transfer a pattern on a predetermined photo resist film, namely transmission light intensity does not expose the photo resist film, when the phase shift mask 40 is used to expose the photo resist film. The halftone region 42 is provided to increase the resolution of the mask 40, and should not be transferred on the photo resist film.

The auxiliary pattern region 43 extends along the outer periphery of the translucent regions 41a and 41b, and the halftone region 42 so as to surround them. The auxiliary pattern region 43 is set such that exposure light transmitting through it has almost the same phase as that of transmission light transmitting through the translucent regions 41a and 41b.

The auxiliary pattern region 43 has a fairly lower transmission factor than that of the translucent regions 41a and 41b. The transmission factor of the auxiliary pattern region 43 is set such that when the phase shift mask 40 is used to expose a predetermined photo resist film, the transmission light through the auxiliary pattern region 43 does not transfer a pattern on the photo resist film, namely the transmission light intensity is set so as not to expose the photo resist film. The auxiliary pattern region 43 is provided to increase the focal depth of the mask 40, and is not to be transferred on the photo resist film.

(Manufacture of Mask of Third Embodiment)

The phase shift mask 40 shown in FIGS. 9A and 9B comprises a mask substrate formed by sequentially laminating a halftone film 122, a transparent film 124, and a light shield film 123 on the transparent substrate 121 as the phase shift mask 30 in FIGS. 8A and 8B. This phase shift mask 40 is manufactured by selectively etching the halftone film 112, the transparent film 114, and the light shield mask 113 of the mask substrate as follows.

First, an electron beam lithography device is used to lithograph the hole forming translucent regions 41a and 41b on a photo resist film (not shown in the drawing) formed on the light shield film 123 based on data for defining the hole forming patterns 21a and 21b shown in FIGS. 9A and 9B. When the photo resist film is developed, openings are formed at positions corresponding to the translucent regions 41a and 41b on the photo resist film. Dry etching selectively removes the light shield film 123, the transparent film 124, and the halftone film 122 while the patterned photo resist film is used as a mask. Square openings 123a and 123b are formed on the light shield film 123, square openings 124a and 124b are formed on the transparent film 124, and square openings 122a and 122b are formed on the halftone film 122. Then, this photo resist film is removed.

Then, the same electron beam lithography device is used to lithograph the halftone region 42 on a resist film (not shown in the drawing) formed on the light shield film 123 based on data for the halftone region forming part 24 shown in FIGS. 9A and 9B. When this photo resist film is developed, an opening is formed at a position corresponding to the halftone region 42. Dry etching selectively removes the light shield film 123 and the transparent film 124 to expose the underlying halftone film 122 while this photo resist film is used as a mask. Openings 123c and 124c in a rectangular shape (a stripe shape) corresponding to the halftone region 42 are respectively formed on the light shield film 123 and the transparent film 124. Then, the photo resist film is removed.

Then, the same electron beam lithography device is used to lithograph the auxiliary pattern region 43 on another resist film (not shown in the drawing) formed on the light shield film 123 based on data for the auxiliary pattern region forming part 25a. When this photo resist film is developed, an opening is formed at a position corresponding to the auxiliary pattern region 43. Dry etching selectively removes the light shield film 123 to expose the underlying transparent film 124 while this photo resist film is used as a mask. In this way, an opening 123d in a rectangular shape corresponding to the auxiliary pattern region 43 is formed on the light shield film 123. Then, the resist film is removed.

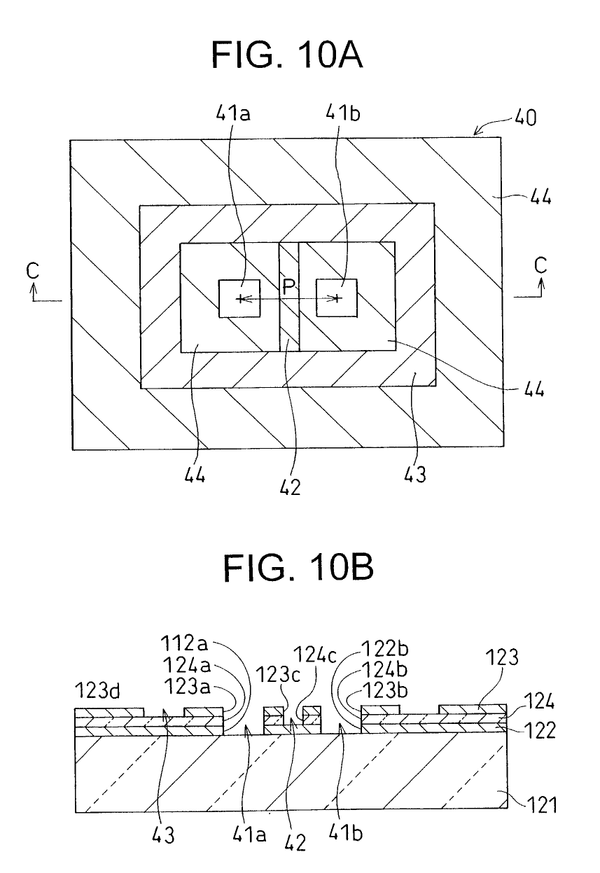

In this way, the halftone/auxiliary pattern type phase shift mask 40 with a constitution as shown in FIGS. 10A and 10B is formed. Namely, the halftone region 42 is placed between the two square translucent regions 41a and 41b, and simultaneously, the auxiliary pattern region 43 in a rectangular ring shape is placed around the translucent regions 41a and 41b. A remaining region between any two of the auxiliary pattern region 43, the translucent regions 41a and 41b, and the halftone region 42, and the outside of the auxiliary pattern region 43 is set to the light shield region 44.

Because the exposure light transmits through the transparent film 124 and the halftone film 122 in the auxiliary pattern region 43, the auxiliary pattern region 33 is semitransparent. While the halftone film 122 is set to shift the phase of the transmitting exposure light by 180° as in the first embodiment, the transparent film 124 is also set to shift the phase of the transmitting exposure light by 180°, and the phase of the exposure light transmitting through the auxiliary pattern region 43 is the same as that of the exposure light transmitting through the hole forming translucent regions 41a and 41b.

When predetermined exposure light is irradiated on the phase shift mask 40, the exposure light transmits through the translucent regions 41a and 41b, the halftone region 42, and the auxiliary pattern region 43. Because it is set such that the phase of the exposure light transmitting through the semitransparent auxiliary pattern region 43 is the same as that of the exposure light transmitting through the hole forming translucent regions 41a and 41b, it is possible to extend the focal depth of the exposure light transmitting through the hole forming translucent regions 41a and 41b.

The effect of decreasing the intensity of the exposure light transmitting through the halftone region 42 changes according to the area of the halftone region 42 and the transmission factor T with respect to the exposure light. The effect of decreasing the intensity of the transmission light decreases as the transmission factor T of the halftone region 42 increases, and the area of the halftone region 42 increases. With the phase shift mask 40 of the third embodiment of the present invention, when the transmission factor T and the area of the halftone region 42 are properly set, such a problem as the hole forming patterns 41a and 41b transferred on the wafer become excessively larger than desired sizes, and the hole forming patterns 41a and 41b transferred on the wafer are connected with each other in an extreme case is solved.

In this way, the phase shift mask 40 of the third embodiment provides the effect of increasing the precision of the transferred hole dimension in the first embodiment, and the effect of extending the focal depth in the second embodiment.

(Design Method for Mask of Third Embodiment)

FIGS. 9A and 9B are conceptual drawings for showing a design method for the phase shift mask 40 (see FIGS. 10a and 10B) of the third embodiment of the present invention described above.

First, the two square hole forming patterns 21a and 21b are placed at the pitch P as shown in FIGS. 9A and 9B on a display device (not shown) of a CAD device.

Then, a first virtual region 22a and a second virtual region 23a are set with respect to the hole forming pattern 21a as shown in the second embodiment. The first virtual region 22a and the second virtual region 23a are magnified (resized) using different ratios while their centers are maintained to coincide with that of the hole forming pattern 21a as in the second embodiment. Thus, both of the virtual regions 22a and 23a are squares. Δ1 and Δ2 respectively represent resize quantities for the virtual regions 22 and 23 (Δ1<Δ2). The resize quantity Δ1 is the same as the resize quantity Δ obtained in the first embodiment.

In the same way, a first virtual region 22b and a second virtual region 23b are respectively set for the other hole forming pattern 21b. The resize quantities are Δ1 and Δ2, which are the same as those for the hole forming pattern 21a.

The first virtual regions 22a and 22b of the hole forming patterns 21a and 21b partially overlap each other, and a rectangular (a stripe-shape) overlap 24 is formed as shown in FIGS. 9A and 9B. The overlap 24 is set to a “halftone region forming part” with the transmission factor T in the third embodiment as in the first embodiment. Exposure light transmitting through the halftone region 42 corresponding to the “halftone region forming part 24” is set such that its phase is different from that of exposure light transmitting through the neighboring transparent regions 21a and 21b by 180°. In this way, deformation of the hole forming patterns 21a and 21b transferred on a wafer is restrained.

Though the second virtual regions 23a and 23b of the hole forming patterns 21a and 21b partially overlap each other, this overlap is neglected. A part where the two second virtual regions 23a and 23b surround the two first virtual regions 22a and 22b, in other words, a part between the first virtual region 22a and the second virtual region 23b, and a part between the first virtual region 22b and the second virtual region 23b, namely a region of (Δ2−Δ1), is set as an “auxiliary pattern forming part 25a”.

A semitransparent auxiliary pattern is formed on the auxiliary pattern region 43 formed corresponding to this auxiliary pattern region forming part 25a. The phase of the exposure light transmitting through the semitransparent auxiliary pattern is the same as that of the exposure light transmitting through the hole forming translucent regions 41a and 41b. In this way, it is possible to extend the focal depth of the exposure light transmitting through the hole forming translucent regions 41a and 41b.

(Specific Example of Mask of Third Embodiment)

As described above, when the transmission factor T and the area S of the halftone region forming part 24 are adjusted, the curve of the transferred hole dimension comes close to flat. When the transmission factor T′ and the area S′ of the auxiliary pattern region forming part 25a are adjusted, the focal depth of the exposure light increase. The following section describes an actual test conducted by the inventors to show a specific example.

The phase shift mask 40 of the third embodiment was used to transfer and form square holes with an edge L of 0.16 μm on a photo resist film on a wafer in this test. The minimum and maximum values of the placement pitch P of these holes are 0.30 μm and 1.5 μm as in the test of the first embodiment.

Though the wavelength λ is 248 nm and NA is 0.68 as the optical conditions of the exposure light as in the test of the first embodiment, the maximum σ of the ⅔ zonal illumination (an illumination using a circular aperture to shield light in a range from the center to ⅔ of the radius) is 0.85, which is slightly larger than that (σ=0.75) in the first embodiment.

A bias of 0.02 μm is added to the individual dimensions of the mask 40. Namely, while the edge L of a hole of a square to be formed is 0.16 μm, the edge L of the square is set to 0.18 μm during the design. The “bias” is added because a dimension change of the hole to be transferred on a waver is decreased.

The transmission factor T of the halftone region 42 is set to three types of 2%, 3%, and 4%, the second resize quantity Δ2 is set to three types of 0.32 μm, 0.36 μm, and 0.40 μm, and the first resize quantity Δ1 is set to three types of 0.12 μm, 0.14 μm, and 0.16 μm. Namely, the relationship between the placement pitch P and the transferred hole dimension is calculated for total of 27 cases.

The transmission factor T of the halftone region 42 is determined as follow. Namely, if it is assumed that parts other than the hole forming translucent regions 41a and 41b are set to the halftone region 42 on the mask 40 when the two forming patterns 21a and 21b are placed at the minimum pitch of 0.3 μm, the dimension becomes the same as the transferred hole dimension in the case where the isolated (namely the pitch is 1.5 μm) hole forming pattern 21 is used when the transmission factor T is 3%. Thus, the transmission factor T of the halftone region 42 is set to 3%.

It is assumed that the semitransparent auxiliary pattern region 43 provides the focal depth extension effect when the center distance of the auxiliary pattern region 43 and the hole forming transparent regions 41a and 41b is similar to the center distance of the auxiliary pattern region and the hole forming translucent regions of the conventional auxiliary pattern type phase shift mask (about 0.3 to 0.4 μm). Because the center distance of the auxiliary pattern region 43 and the hole forming translucent regions 41a and 41b is given by:

(½) (Δ1=Δ2=L)

the optimal values for the firs resize quantity Δ1 and the second resize quantity Δ2 are obtained to satisfy:

(½) (Δ1=Δ=L)=about 0.3 to 0.4 μm.

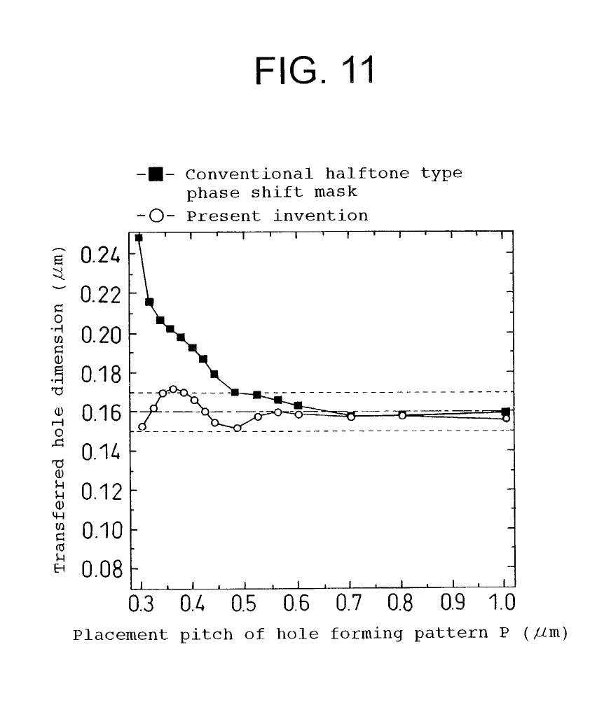

FIG. 11 shows the result.

As FIG. 11 clearly shows, the fluctuation of the transferred hole dimension is minimum when the transmission factor T is 3%, the first resize quantity Δ1 is 0.12 μm, and the second resize quantity Δ2 is 0.36 μm (curves for other cases are suppressed in FIG. 11).

The oblique incident component of the zone illumination is slightly stronger than that in the first embodiment, and the “mask bias” of 0.02 μm is added in the third embodiment. The transferred hole dimension is larger than 0.24 μm for the minimum pitch of 0.3 μm when the conventional halftone type phase shift mask has the same constitution as that in the third embodiment except for the auxiliary pattern region 43.

In an actual exposure, a “thickness reduction” phenomenon arises when the width of a resist film remaining between the two hole forming patterns is 0.13 μm or less, the resolution is difficult for a pitch of 0.32 μm or less for the conventional halftone type phase shift mask.

On the other hand, though the transferred hole dimension is larger than a desired dimension (0.16 μm) by slightly larger than 0.01 μm when the pitch P is 0.36 μm the difference from the desired dimension (0.16 μm) is restrained to ±0.012 μm or less for all pitches for the halftone/auxiliary pattern type phase shift mask 40 of the third embodiment. Because the semitransparent auxiliary pattern region 43 decreases the intensity of the transmission light in a range where the pitch P is small, the problem of the “thickness reduction” does not arise in the photo resist film remaining between the two hole forming translucent regions 41a and 41b.

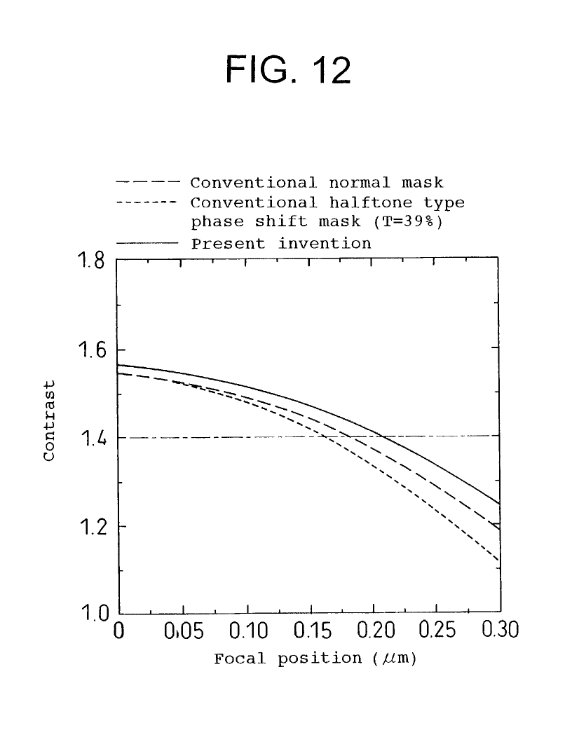

FIG. 12 is a chart for showing a relationship between a contrast of an isolated hole forming pattern, and the focal position, and indicates the extension effect for the focal depth by the second embodiment and the third embodiment.

In FIG. 12, the contrast is defined as:

Contrast=(Peak light intensity at individual focus

position)/(threshold of light intensity when the dimension

is 0.16 μm at the best focus position).

If it is assumed that a hole forming pattern is opened on a resist film when the contrast defined as described above is 1.4 or more, the focal depth of the conventional mask is ±0.18 μm. The focal depth for the masks 30 and 40 increases up to ±0.21 μm for the second embodiment and the third embodiment.

For the conventional mask shown in FIG. 12, the focal depth decreases to the contrary. This is because the phase of the transmission light of the auxiliary pattern regions 33 and 43 is shifted by 180° to the phase of the transmission light of the hole forming translucent regions 31, 41a, and 41b.

While the auxiliary pattern regions 33 and 43 are half transparent in the second embodiment and the third embodiment, it is possible to form these regions 33 and 43 as narrow transparent regions. Namely, a similar focal depth extension effect is provided when the difference between the first and second resize quantities Δ1 and Δ2 (Δ2−Δ1) is reduced, and the conventional minute auxiliary pattern (transmission factor is almost 100%) is formed on the region for (Δ2−Δ1).

(Variations)

The first to third embodiments described above show specific examples of the present invention, and the present invention is not limited to these embodiments. It is obvious that different types of variations can be provided while following the purpose of the present invention.

For example, while the present invention is applied to photolithography using light, and uses a hole pattern as a main pattern in the embodiments, the present invention is not limited to them. While it is assumed that the photo resist film is positive type in these embodiments, the present invention is applied to a case where the photo resist film is negative type.

The present invention is not limited by the wavelength of the exposure light, and the types of the mask such as transparent type and the reflective type. For example, while a halftone type phase shift mask has recently been proposed for an X ray same size translucent type mask, and a reflective size reduction mask, the present invention is applied to them.

As described above, the halftone type phase shift mask and the design method for it provide such effects as the time required for setting the “halftone region” and the “auxiliary pattern” is reduced, and consequently, a phase shift mask including the “halftone region” and the “auxiliary pattern” is easily manufactured.

When the mask includes the “halftone” region, such an additional effect as the deformation of transferred patterns to be transferred on a wafer with respect to original patterns placed at a predetermined pitch on a mask is effectively restrained is provided. When the mask includes the “auxiliary pattern”, such an additional effect as the focal depth extends is provided.

What is claimed is:

1. A design method for a phase shift mask comprising the steps of:
placing a plurality of main patterns at a predetermined pitch;
extending said individual main patterns by a predetermined resize quantity to form virtual regions;
placing an overlapped part between their two virtual regions, and setting it as a halftone region forming part having a predetermined transmission factor with respect to exposure light when the two neighboring virtual regions have the overlapped part; and
setting such that said halftone region forming part does not exist when the two neighboring virtual regions do not have an overlapped part,
wherein said resize quantity and said transmission factor are set such that a transferred size of said main patterns on a predetermined resist film is settled within a desired range according to the change of said pitch under a predetermined exposure condition.

2. The design method for a phase shift mask according to claim 1, wherein said resize quantity and said transmission factor are set such that a fluctuation of the transferred dimension of said main patterns on said resist film is approximately the minimum according to the change of said pitch.

3. The design method for a phase shift mask according to claim 1, wherein said halftone region forming part is placed along the perpendicular bisector of a line connecting the centers of said neighboring two main patterns with each other.

4. A phase shift mask comprising:
a plurality of main pattern forming translucent regions formed on the surface of a substrate at a predetermined pitch;
a halftone region formed between said two neighboring main pattern forming translucent regions on the surface of said substrate; and
a light shield region formed on a part other than said main pattern forming translucent regions and said halftone region on the surface of said substrate,
wherein said halftone region has a feature for making exposure light transmitting through the halftone region attenuate the intensity of said exposure light transmitting through said main pattern forming translucent regions, and the position, the shape, and the size of said halftone region are equivalent to the position, the shape, and the size of a part where virtual regions obtained by extending said individual main pattern forming translucent regions by a predetermined resize quantity overlap each other.

5. The phase shift mask according to claim 4 further comprising:
a halftone film formed on the surface of said substrate; and
a light shield film formed on the halftone film, wherein said halftone region is defined by a first opening formed on said light shield film, and said main pattern forming translucent regions are defined by second openings formed on said light shield film, and openings formed on said halftone film.

6. The phase shift mask according to claim 4, wherein said halftone region is placed along the perpendicular bisector of a line connecting the centers of said neighboring two main patterns with each other.

7. A design method for a phase shift mask comprising the steps of:
placing a main pattern;
extending said main pattern by a predetermined first resize quantity to form a first virtual region;
extending said main pattern by a predetermined second resize quantity larger than said first resize quantity to form a second virtual region; and
setting a part between said second virtual region and said first virtual region to an auxiliary pattern forming part having a predetermined transmission factor,
wherein said first resize quantity and said second resize quantity are set such that a desired focal depth extension effect is obtained for exposure light under a predetermined exposure condition.

8. The design method for a phase shift mask according to claim 7, wherein said auxiliary pattern forming part is formed as a ring concentric with said main pattern.

9. A phase shift mask comprising:
a main pattern forming translucent region formed on the surface of a substrate;
an auxiliary pattern region in a ring shape formed around said main pattern forming translucent region on the surface of said substrate; and
a light shield region formed on a part other than said main pattern forming translucent region and said auxiliary pattern region,
wherein said auxiliary pattern region has a feature for making exposure light transmitting through the auxiliary pattern region attenuate the intensity of said exposure light transmitting through said main pattern forming translucent region, and the position, the shape, and the size of said auxiliary pattern region are equivalent to the position, the shape, and the size of a part between a first virtual region obtained by extending said main pattern forming translucent region by a first resize quantity, and a second virtual region obtained by extending said main pattern forming translucent region by a second resize quantity larger than the first resize quantity.

10. The phase shift mask according to claim 9 further comprising:
a halftone film formed on the surface of said substrate;
a transparent film formed on the halftone film; and
a light shield film formed on the transparent film,
wherein said auxiliary pattern region is defined by a first opening formed on said light shield film, and said main pattern forming translucent region is defined by a second opening formed on said light shield film, and an opening formed on said halftone film.

11. A design method for a phase shift mask comprising the steps of:
placing a plurality of main patterns at a predetermined pitch;
extending said individual main patterns by a predetermined first resize quantity to form first virtual regions;
extending said individual main patterns by a predetermined second resize quantity larger than said first resize quantity to form second virtual regions;
placing an overlapped part between the two first virtual regions, and setting it as a halftone region forming part having a predetermined transmission factor with respect to exposure light when the two neighboring first virtual regions have the overlapped part;
setting such that said halftone region forming part does not exist when the two neighboring first virtual regions do not have an overlapped part; and
setting a part where said two second virtual regions surround said two first virtual regions corresponding to them to an auxiliary pattern forming part having a predetermined transmission factor,
wherein said first resize quantity and the transmission factor of said halftone region forming part are set such that a transferred size of said main patterns on a predetermined resist film is settled within a desired range according to the change of said pitch under a predetermined exposure condition, and said second resize quantity is set such that a desired focal depth extension effect is obtained for said exposure light under said predetermined exposure condition.

12. The design method for a phase shift mask according to claim 11, wherein said first resize quantity and the transmission factor of said halftone region forming part are set such that a fluctuation of the transferred dimension of said main patterns on said resist film is approximately the minimum according to the change of said pitch.

13. The design method for a phase shift mask according to claim 11, wherein said halftone region forming part is placed along the perpendicular bisector of a line connecting the centers of said neighboring two main patterns with each other.

14. The design method for a phase shift mask according to claim 11, wherein said auxiliary pattern forming part is formed as a ring concentric with said main pattern.

15. A phase shift mask comprising:
a plurality of main pattern forming translucent regions formed on the surface of a substrate at a predetermined pitch;
a halftone region formed between said two neighboring main pattern forming translucent regions on the surface of said substrate;
an auxiliary pattern region in a ring shape formed around said neighboring two main pattern forming translucent regions on the surface of said substrate; and
a light shield region formed on a part other than said main pattern forming translucent regions, said halftone region, and said auxiliary pattern region on the surface of said substrate,
wherein said halftone region has a feature for making exposure light transmitting through the halftone region attenuate the intensity of said exposure light transmitting through said main pattern forming translucent regions, the position, the shape, and the size of said halftone region are equivalent to the position, the shape, and the size of an region where virtual regions obtained by extending said individual main pattern forming translucent regions by a predetermined resize quantity overlap each other, said auxiliary pattern region has a feature for making exposure light transmitting through the auxiliary pattern region attenuate the intensity of said exposure light transmitting through said main pattern forming translucent regions, and the position, the shape, and the size of said auxiliary pattern region are equivalent to the position, the shape, and the size of an region between a first virtual region obtained by extending said main pattern forming translucent region by a first resize quantity, and a second virtual region obtained by extending said main pattern forming translucent region by a second resize quantity larger than the first resize quantity.

16. The phase shift mask according to claim 15 further comprising:
a halftone film formed on the surface of said substrate;
a transparent film formed on the halftone film; and
a light shield film formed on the transparent film,
wherein said halftone region is defined by a first opening formed on said light shield film and the first opening formed on said transparent film, said auxiliary pattern region is defied by a second opening formed on said light shield film, and said individual main pattern forming translucent regions are defined by third openings formed on said light shield film, the second opening formed on said translucent film, and openings formed on said halftone film.

17. The phase shift mask according to claim 15, wherein said halftone region is placed along the perpendicular bisector of a line connecting the centers of said neighboring two main patterns with each other.
